(19) United States
(12) Patent Application Publication
(10) Pub. No.: US 2018/0182779 A1
(43) Pub. Date: Jun. 28, 2018

(54) TFT ARRAY SUBSTRATE AND MANUFACTURING METHOD THEREOF

(71) Applicant: Wuhan China Star Optoelectronics Technology Co. Ltd., Wuhan City (CN)

(72) Inventor: Wenqing Song, Wuhan City (CN)

(21) Appl. No.: 15/115,687

(22) PCT Filed: May 17, 2016
(86) PCT No.: PCT/CN2016/082411

§ 371 Date: Jul. 31, 2016

(30) Foreign Application Priority Data
Apr. 18, 2016 (CN) 201610240476.1

(51) Int. Cl. H01L 27/12; H01L 29/786; H01L 29/45; H01L 29/66; H01L 21/02

(52) U.S. Cl. CPC H01L 27/124; H01L 27/1218; H01L 27/1248; H01L 29/78678; H01L 29/458; H01L 29/66765; G02F 1/136227; H01L 21/02532; H01L 21/02592; H01L 27/1274; H01L 21/02667; H01L 27/1288; H01L 27/1222; H01L 27/1262

(57) ABSTRACT

The present invention provides a TFT array substrate and a manufacturing method thereof. The TFT array substrate is structured such that a source electrode (240) and a drain electrode (250) of a TFT (200) are formed on a gate insulation layer (220) and a data line (400) is formed on a first passivation protection layer (300) that is set on and covers the source electrode (240) and the drain electrode (250) of the TFT (200) so that the data line (400) and the source electrode (240) and the drain electrode (250) of the TFT (200) are located on different layers and flexible adjustment of a spacing distance between the data line (400) and the gate electrode (210) can be achieved by varying a thickness of the first passivation protection layer (300). Compared to the prior art, the spacing distance between the data line (400) and the gate electrode (210) is expanded, parasitic capacitance between the data line (400) and the gate electrode (210) is reduced, power consumption of the data line (400) is reduced, while a thickness of the gate insulation layer (220) is not affected and positions of the source electrode (240) and the drain electrode (250) of the TFT (200) are not changed so as to maintain characteristics of the TFT stable.

### BACKGROUND OF THE INVENTION

### 1. Field of the Invention

The present invention relates to the field of liquid crystal display technology, and in particular to a thin-film transistor (TFT) array substrate and a manufacturing method thereof.

### 2. The Related Arts

Liquid crystal displays (LCDs) are one of the flat panels displays that are most commonly used today. A liquid crystal display panel is a core constituent component of an LCD.

A liquid crystal display panel is generally made up of a color filter (CF) substrate, a thin-film transistor (TFT) array substrate, and a liquid crystal layer arranged between the two substrates, wherein the TFT array substrate comprises TFTs that are arranged in an array formed thereon for driving liquid crystal to rotate in order to control displaying with each pixel, while the CF substrate comprises a color filter layer formed thereon for generating color for each pixel. The working principle of the liquid crystal display panel is that through application of a drive voltage to the FTF array substrate and the CF substrate to control the rotation of liquid crystal molecules contained in the liquid crystal layer in order to refract out light emitting from a backlight module to generate an image.

The LCD technology has getting mature nowadays and the primary direction of development today is to reduce the power consumption of the liquid crystal display panels.

Referring to FIG. 1, a schematic view is given to illustrate the structure of a conventional thin-film transistor (TFT) array substrate, which comprises: a backing plate 100′, a gate electrode 200′ formed on the backing plate 100′, a gate insulation layer 300′ formed on the gate electrode 200′, an active layer 400′ formed on the gate insulation layer 300′ and corresponding, in position, to the gate electrode 200′, a source electrode 500′ and a drain electrode 600′ formed on the gate insulation layer 300′ and the active layer 400′ to be respectively in engagement with two ends of the active layer 400′, a data line 700′ formed on the gate insulation layer 300′ and located on the same layer as the source electrode 500′ and the drain electrode 600′, a passivation protection layer 800′ set on and covering the gate insulation layer 300′, the source electrode 500′, the drain electrode 600′, and the data line 700′, and a pixel electrode 900′ formed on the passivation protection layer 800′, wherein the pixel electrode 900′ is set in engagement with the source electrode 500′ through a via 810′ that extends through the passivation protection layer 800′.

In the conventional TFT array substrate, parasitic capacitance Cgd may be generated between the data line 700′ and the gate electrode 200′ by following the formula: Cgd=ε₀εᵣ s/d, wherein ε₀ is the dielectric constant of vacuum, εᵣ is relative dielectric constant of the material, s indicates the area of a surface of the data line 700′ opposing the gate electrode 200′, and d is the spacing distance between the data line 700′ and the gate electrode 200′, which is a thickness of the gate insulation layer 300′.

To reduce power consumption of the data line 700′, the level of the parasitic capacitance Cgd must be reduced. Since the parasitic capacitance Cgd is inversely proportional to the spacing distance between the data line 700′ and the gate electrode 200′, the spacing distance between the data line 700′ and the gate electrode 200′ can be increased by expanding the thickness of the gate insulation layer 300′ in order to reduce the parasitic capacitance Cgd. However, the source electrode 500′ and the drain electrode 600′ of the TFT and the data line 700′ are located on the same layer with all of them formed on the gate insulation layer 300′, so that varying the thickness of the gate insulation layer 300′ to control the parasitic capacitance Cgd would inevitably cause changes of the positions of the source electrode 500′ and the drain electrode 600′ and thus affecting the characteristics of the TFT. Thus, the conventional TFT array substrate shown in FIG. 1 does not allow for flexible adjustment of the parasitic capacitance Cgd.

### SUMMARY OF THE INVENTION

An object of the present invention is to provide a thin-film transistor (TFT) array substrate, which, under the condition of maintaining TFT characteristics, allows for flexible adjustment of a spacing distance between a data line and a gate electrode in order to reduce parasitic capacitance between the data line and the gate electrode and thus reduce power consumption of the data line.

Another object of the present invention is to provide a manufacturing method of a TFT array substrate, which maintains the TFT characteristics and also reduces parasitic capacitance between a data line and a gate electrode and reduces power consumption of the data line.

To achieve the above objects, the present invention provides a TFT array substrate, which comprises: a backing plate, a TFT formed on the backing plate, a first passivation protection layer set on and covering the TFT, a data line formed on the first passivation protection layer, a second passivation protection layer set on and covering the first passivation protection layer and the data line, and a pixel electrode formed on the second passivation protection layer;

wherein the TFT comprises: a gate electrode formed on the backing plate, a gate insulation layer set on and covering the gate electrode and the backing plate, an active layer formed on the gate insulation layer and located exactly above the gate electrode, and a source electrode a drain electrode formed on the gate insulation layer and respectively in contact engagement with two ends of the active layer; and

a first via is formed above the drain electrode and extends through the first passivation protection layer and the data line is set in contact engagement with the drain electrode through the first via.

The source electrode, the drain electrode, and the data line are formed of the same metallic material

The material of the source electrode, the drain electrode, and the data line comprises one of molybdenum, titanium, aluminum, and copper or a stacked combination of multiple ones thereof.

The backing plate comprises a glass plate; the pixel electrode is formed of a material comprising indium tin oxide (ITO); and the gate insulation layer, the first passivation protection layer, and the second passivation protection layer are formed of a material comprising silicon nitride, silicon oxide, or a combination thereof.

A second via is formed above the source electrode and extends through the first passivation protection layer and the second passivation protection layer and the pixel electrode is set in contact engagement with the source electrode through the second via.

The present invention also provides a manufacturing method of a TFT array substrate, which comprises the following steps:

(1) providing a backing plate and depositing and patterning a first metal layer on the backing plate to form a gate electrode;

(2) depositing a gate insulation layer on the gate electrode and the backing plate;

(3) forming an active layer on the gate insulation layer to be located exactly above the gate electrode;

(4) conducting a first round of depositing and patterning a second metal layer on the gate insulation layer and the active layer to form a source electrode and a drain electrode that are respectively in contact engagement with two ends of the active layer so as to complete formation of a TFT;

(5) depositing and covering a first passivation protection layer on the source electrode, the drain electrode, and the gate insulation layer and conducting patterning treatment on the first passivation protection layer to form a first via that is located above the drain electrode and extends through the first passivation protection layer;

(6) conducting a second round of depositing and patterning a second metal layer on the first passivation protection layer to form a data line, such that the data line is set in contact engagement with the drain electrode through the first via;

(7) depositing and covering a second passivation protection layer on the first passivation protection layer and the data line and conducting patterning treatment to form a second via that is located above the source electrode and extends through the second passivation protection layer and the first passivation protection layer; and

(8) depositing and patterning a transparent conductive film on the second passivation protection layer to form a pixel electrode, such that the pixel electrode is set in contact engagement with the source electrode through the second via.

The second metal layer is formed of a material comprising one of molybdenum, titanium, aluminum, and copper or a stacked combination of multiple ones thereof.

The backing plate comprises a glass plate; the transparent conductive film comprises an ITO film; and the gate insulation layer, the first passivation protection layer, and the second passivation protection layer are formed of a material comprising silicon nitride, silicon oxide, or a combination thereof.

The present invention further provides a TFT array substrate, which comprises: a backing plate, a TFT formed on the backing plate, a first passivation protection layer set on and covering the TFT, a data line formed on the first passivation protection layer, a second passivation protection layer set on and covering the first passivation protection layer and the data line, and a pixel electrode formed on the second passivation protection layer;

wherein the TFT comprises: a gate electrode formed on the backing plate, a gate insulation layer set on and covering the gate electrode and the backing plate, an active layer formed on the gate insulation layer and located exactly above the gate electrode, and a source electrode a drain electrode formed on the gate insulation layer and respectively in contact engagement with two ends of the active layer; and

a first via is formed above the drain electrode and extends through the first passivation protection layer and the data line is set in contact engagement with the drain electrode through the first via;

wherein the source electrode, the drain electrode, and the data line are formed of the same metallic material; and

wherein the backing plate comprises a glass plate; the pixel electrode is formed of a material comprising indium tin oxide (ITO); and the gate insulation layer, the first passivation protection layer, and the second passivation protection layer are formed of a material comprising silicon nitride, silicon oxide, or a combination thereof.

The efficacy of the present invention is that the present invention provides a TFT array substrate, in which a source electrode and a drain electrode of a TFT are formed on a gate insulation layer and a data line is formed on a first passivation protection layer that is set on and covers the source electrode and the drain electrode of the TFT so that the data line and the source electrode and the drain electrode of the TFT are located on different layers and flexible adjustment of a spacing distance between the data line and the gate electrode can be achieved by varying the thickness of the first passivation protection layer, whereby compared to the prior art, the spacing distance between the data line and the gate electrode is expanded; parasitic capacitance between the data line and the gate electrode is reduced; power consumption of the data line is reduced; while the thickness of a gate insulation layer is not affected and positions of the source electrode and the drain electrode of the TFT are not changed so that characteristics of the TFT are maintained stable. The present invention provides a manufacturing method of a TFT array substrate, in which a source electrode and a drain electrode of a TFT are first formed on a gate insulation layer and then, a data line is formed on a first passivation protection layer set on and covering the source electrode and the drain electrode of the TFT so as to maintain the characteristics of the TFT and also reduce parasitic capacitance between the data line and the gate electrode to thereby reducing power consumption of the data line.

### BRIEF DESCRIPTION OF THE DRAWINGS

The features and technical contents of the present invention will be better understood by referring to the following detailed description and drawings of the present invention. However, the drawings are provided for the purpose of reference and illustration and are not intended to limit the scope of the present invention.

In the drawing:

FIG. 1 is a schematic view illustrating a conventional thin-film transistor (TFT) array substrate;

FIG. 2 is a schematic view illustrating a TFT array substrate according to the present invention;

FIG. 3 is a flow chart illustrating a manufacturing method of a TFT array substrate according to the present invention.

FIG. 4 is a schematic view illustrating step 1 of the manufacturing method of the TFT array substrate according to the present invention;

FIG. 5 is a schematic view illustrating step 2 of the manufacturing method of the TFT array substrate according to the present invention;

FIG. 6 is a schematic view illustrating step 3 of the manufacturing method of the TFT array substrate according to the present invention;

FIG. 7 is a schematic view illustrating step 4 of the manufacturing method of the TFT array substrate according to the present invention;

FIG. 8 is a schematic view illustrating step 5 of the manufacturing method of the TFT array substrate according to the present invention;

FIG. 9 is a schematic view illustrating step 6 of the manufacturing method of the TFT array substrate according to the present invention;

FIG. 10 is a schematic view illustrating step 7 of the manufacturing method of the TFT array substrate according to the present invention; and

FIG. 11 is a schematic view illustrating step 8 of the manufacturing method of the TFT array substrate according to the present invention.

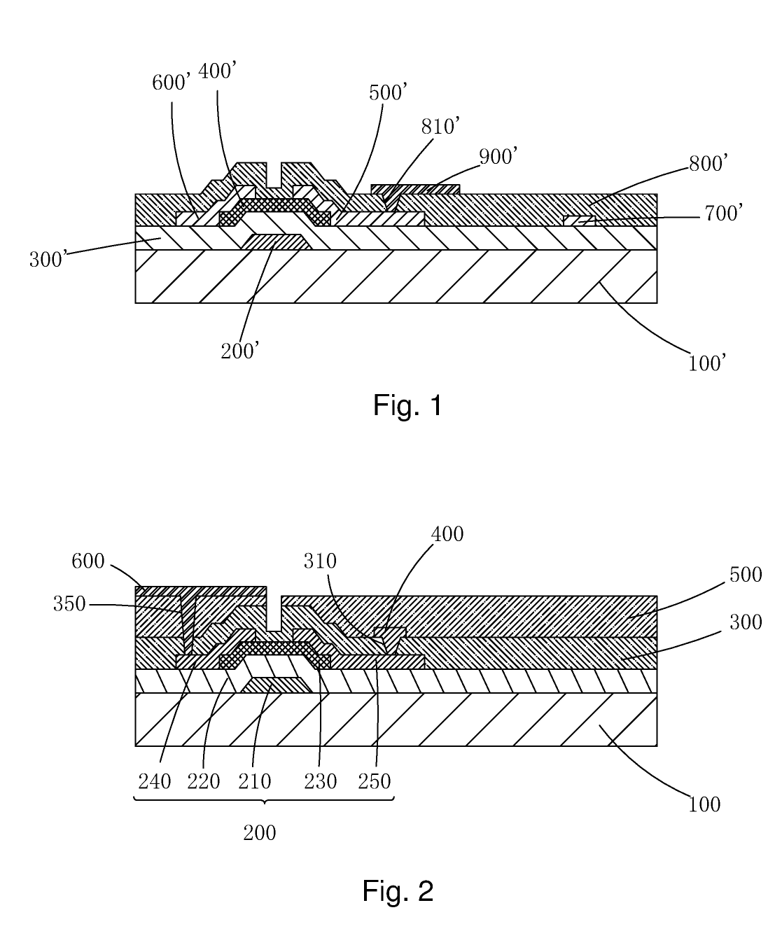

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

Referring to FIG. 2, firstly, the present invention provides a thin-film transistor (TFT) array substrate, which comprises: a backing plate 100, a TFT 200 formed on the backing plate 100, a first passivation protection layer 300 set on and covering the TFT 200, a data line 400 formed on the first passivation protection layer 300, a second passivation protection layer 500 set on and covering the first passivation protection layer 300 and the data line 400, and a pixel electrode 600 formed on the second passivation protection layer 500.

The TFT 200 comprises: a gate electrode 210 formed on the backing plate 100, a gate insulation layer 220 set on and covering the gate electrode 210 and the backing plate 100, an active layer 230 formed on the gate insulation layer 220 and located exactly above the gate electrode 210, and a source electrode 240 and a drain electrode 250 formed on the gate insulation layer 220 and respectively in contact engagement with two ends of the active layer 230.

A first via 310 is formed above the drain electrode 250 and extends through the first passivation protection layer 300 and the data line 400 is set in contact engagement with the drain electrode 250 through the first via 310.

A second via 350 is formed above the source electrode 240 and extends through the first passivation protection layer 300 and the second passivation protection layer 500 and the pixel electrode 600 is set in contact engagement with the source electrode 240 through the second via 350.

Specifically, the backing plate 100 comprises a transparent plate, preferably a glass plate.

The source electrode 240, the drain electrode 250, and the data line 400 are formed of the same metallic material and the metallic material is preferably one of molybdenum (Mo), titanium (Ti), aluminum (Al), and copper (Cu) or a stacked combination of multiple ones thereof.

The gate insulation layer 220, the first passivation protection layer 300, and the second passivation protection layer 500 are formed of a material comprising silicon nitride (SiNx), silicon oxide (SiOx), or a combination thereof.

The pixel electrode 600 comprises a transparent electrode, of which the material is preferably indium tin oxides (ITO).

Further, the data line 400 and the gate electrode 210 can be treated as two metal electrode plates that are opposite to each other and parasitic capacitance Cgd is present between the two. It can be known from a capacitance formula that

Cgd=ε₀εᵣ s/d (1)

where ε₀ indicates the dielectric constant of vacuum, εᵣ is relative dielectric constant of the material, s indicates the area of a surface of the data line 400 opposing the gate electrode 210, and d is the spacing distance between the data line 400 and the gate electrode 210.

In the TFT array substrate of the present invention, since the source electrode 240 and the drain electrode 250 of the TFT 200 are formed on the gate insulation layer 220, while the data line 400 is formed on the first passivation protection layer 300 that is set on and covers the source electrode 240 and the drain electrode 250 of the TFT 200, meaning the data line 400 and the source electrode 240 and the drain electrode 250 of the TFT 200 are located on different layers, the spacing distance between the data line 400 and the gate electrode 210 is the sum of a thickness of the first passivation protection layer 300 and a thickness of the gate insulation layer 220 and, compared to a conventional TFT array substrate, the spacing distance between the data line 400 and the gate electrode 210 is increased by a thickness of the first passivation protection layer 300. It can be known from formula (1) that the parasitic capacitance Cgd is inversely proportional to the spacing distance between the data line 400 and the gate electrode 210 so that an increase of the spacing distance between the data line 400 and the gate electrode 210 would result in a decrease of the parasitic capacitance Cgd thereby effectively reducing power consumption of the data line 400 and thus power consumption of the TFT array substrate. Further, the TFT array substrate of the present invention allows for flexible adjustment of the spacing distance between the data line 400 and the gate electrode 210 by varying the thickness of the first passivation protection layer 300 so as to allow for flexible regulation of the parasitic capacitance Cgd, such as expanding the thickness of the first passivation protection layer 300 to increase the spacing distance between the data line 400 and the gate electrode 210 for decreasing the parasitic capacitance Cgd. It is noted that since the reason that the spacing distance between the data line 400 and the gate electrode 210 is increased is allocating the data line 400 on a layer that is above the first passivation protection layer 300, the thickness of the gate insulation layer 220 is not affected and positions of the source electrode 240 and the drain electrode 250 of the TFT 200 are not changed so that the characteristics of the TFT 200 can be maintained.

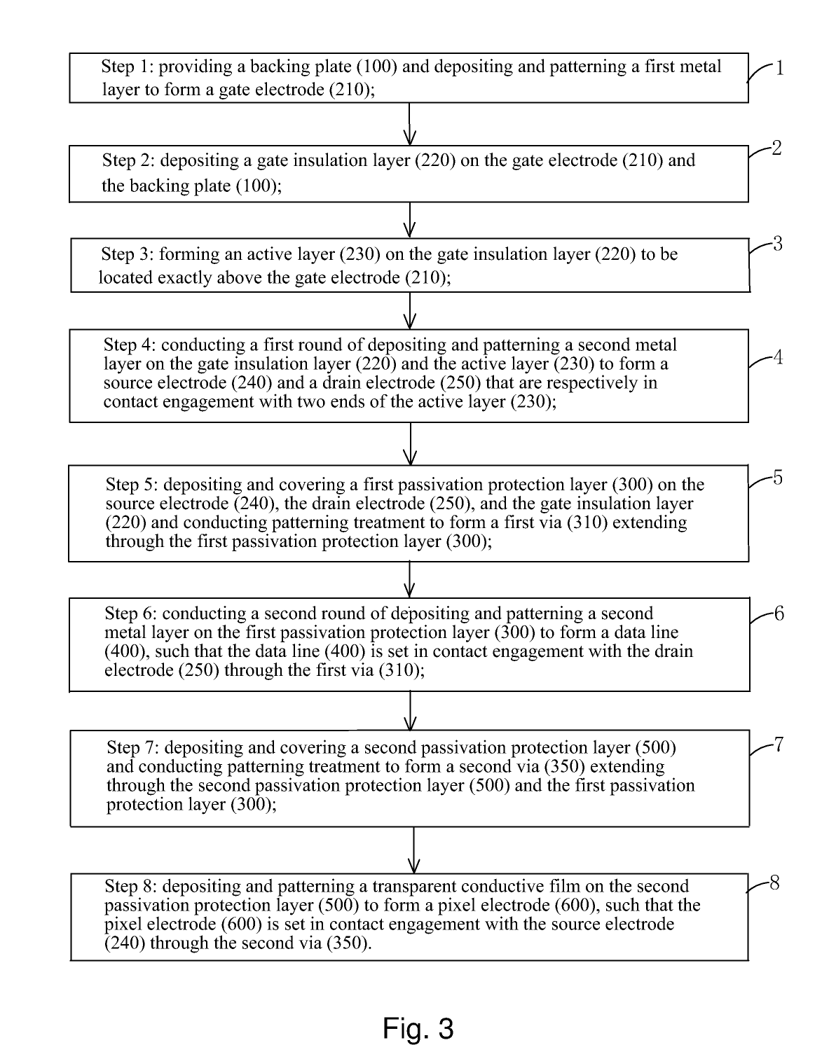

Referring to FIG. 3, based on the same inventive idea, the present invention also provides a manufacturing method of a TFT array substrate, which comprises the following steps:

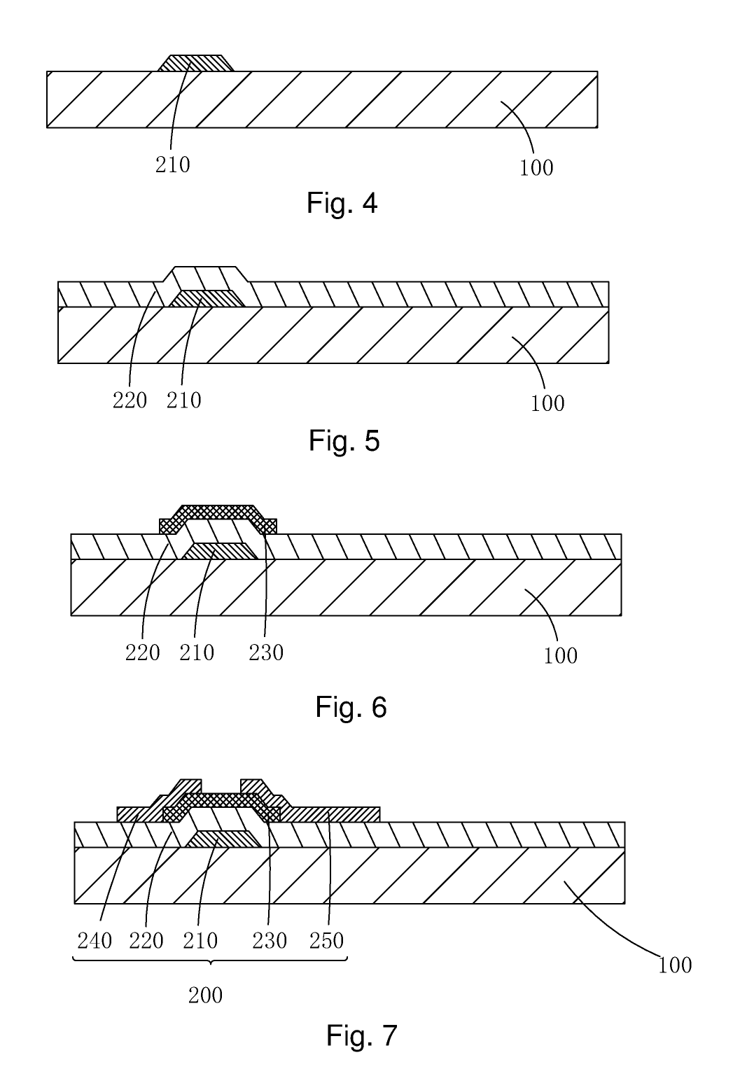

Step 1: as shown in FIG. 4, providing a backing plate 100 and depositing and patterning a first metal layer on the backing plate 100 to form a gate electrode 210.

Specifically, the backing plate 100 comprises a transparent plate, preferably a glass plate.

Step 1 uses a first mask to pattern the first metal layer through an etching operation.

Step 2: as shown in FIG. 5, depositing a gate insulation layer 220 on the gate electrode 210 and the backing plate 100.

Specifically, the gate insulation layer 220 is formed of a material comprising silicon nitride, silicon oxide, or a combination thereof.

Step 3: as shown in FIG. 6, forming an active layer 230 on the gate insulation layer 220 to be located exactly above the gate electrode 210.

Specifically, a detailed process of forming the active layer 230 in Step 3 comprises: firstly, depositing an amorphous silicon layer, and then, conducting crystallization treatment to form a poly-silicon layer, followed by performance of ion implantation, and finally, conducting patterning treatment by using a second mask and applying an etching operation to form the active layer 230.

Step 4: as shown in FIG. 7, conducting a first round of depositing and patterning a second metal layer on the gate insulation layer 220 and the active layer 230 to form a source electrode 240 and a drain electrode 250 that are respectively in contact engagement with two ends of the active layer 230 so as to complete formation of a TFT 200.

Specifically, the second metal layer is formed of a material comprising one of molybdenum, titanium, aluminum, and copper or a stacked combination of multiple ones thereof.

Step 4 uses a third mask to conduct a first round of patterning treatment on the second metal layer with an etching operation in order to form the source electrode 240 and the drain electrode 250.

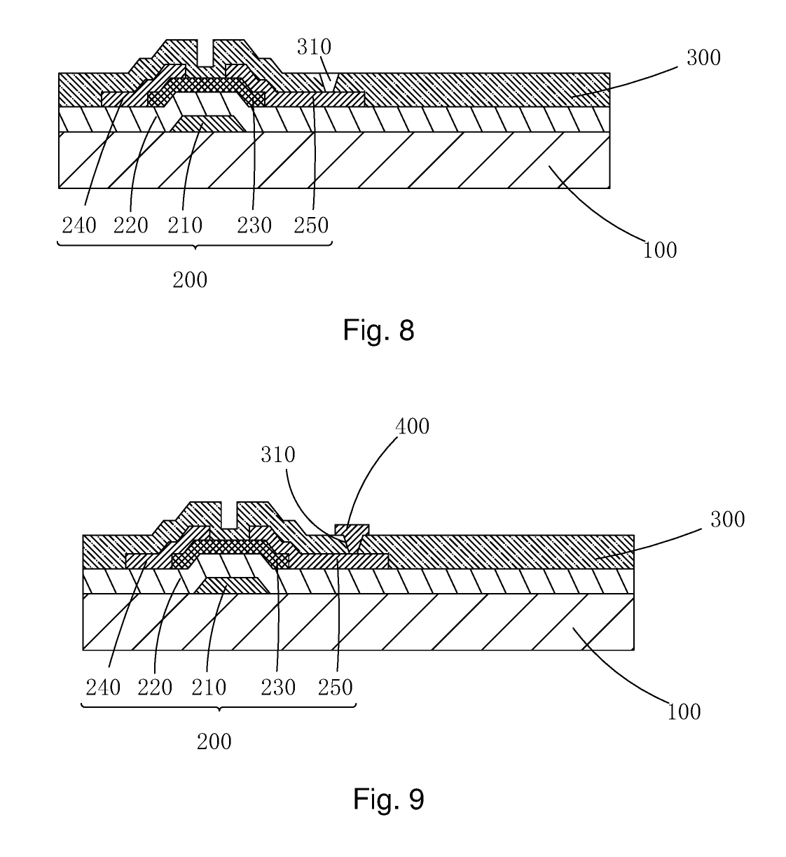

Step 5: as shown in FIG. 8, depositing and covering a first passivation protection layer 300 on the source electrode 240, the drain electrode 250, and the gate insulation layer 220 and conducting patterning treatment on the first passivation protection layer 300 to form a first via 310 that is located above the drain electrode 250 and extends through the first passivation protection layer 300.

Specifically, the first passivation protection layer 300 is formed of a material comprising silicon nitride, silicon oxide, or a combination thereof.

Step 5 uses a fourth mask to pattern the first passivation protection layer 300 with an etching operation.

Step 6: as shown in FIG. 9, conducting a second round of depositing and patterning a second metal layer on the first passivation protection layer 300 to form a data line 400, such that the data line 400 is set in contact engagement with the drain electrode 250 through the first via 310.

Specifically, the second metal layer of Step 6 is of the same material as that of the second metal layer of Step 4 and is similarly one of molybdenum, titanium, aluminum, and copper or a stacked combination of multiple ones thereof.

Step 6 uses a fifth mask to conduct a second round of patterning treatment on the second metal layer with an etching operation in order to form the data line 400.

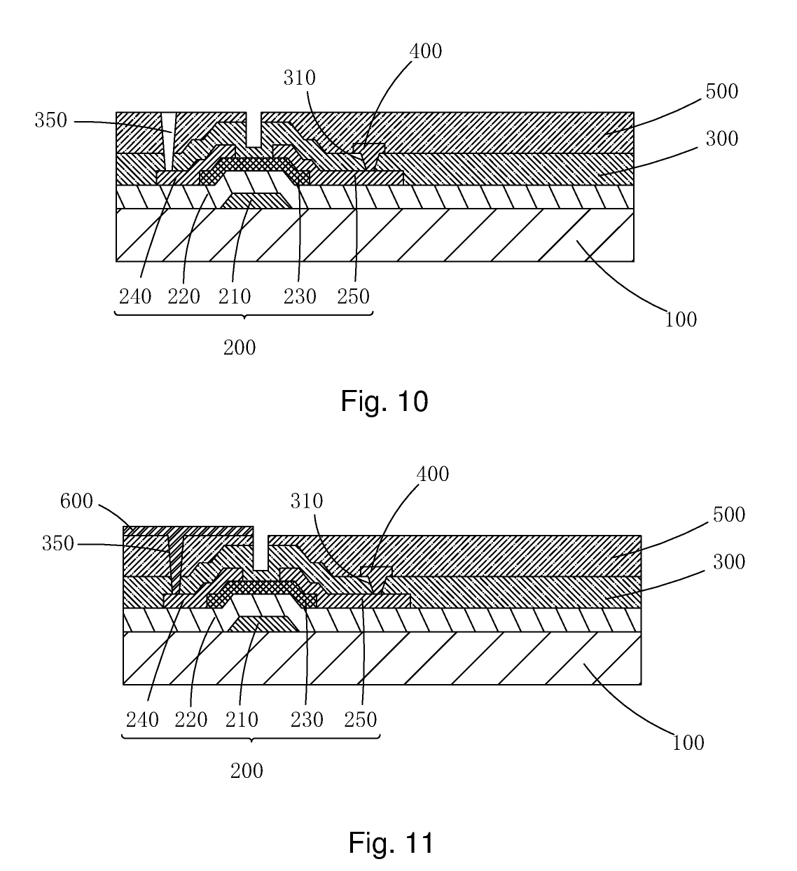

Step 7: as shown in FIG. 10, depositing and covering a second passivation protection layer 500 on the first passivation protection layer 300 and the data line 400 and conducting patterning treatment to form a second via 350 that is located above the source electrode 240 and extends through the second passivation protection layer 500 and the first passivation protection layer 300.

Specifically, the second passivation protection layer 500 is formed of a material comprising silicon nitride, silicon oxide, or a combination thereof.

Step 7 uses a sixth mask to pattern the second passivation protection layer 500 and the first passivation protection layer 300 with an etching operation in order to form the second via 350.

Step 8: as shown in FIG. 11, depositing and patterning a transparent conductive film on the second passivation protection layer 500 to form a pixel electrode 600, such that the pixel electrode 600 is set in contact engagement with the source electrode 240 through the second via 350.

Specifically, the transparent conductive film is an ITO film.

Step 8 uses a seventh mask to pattern the transparent conductive film with an etching operation to form the pixel electrode 600.

The manufacturing method of the TFT array substrate according to the present invention is such that the source electrode 240 and the drain electrode 250 of the TFT 200 are first formed on the gate insulation layer 220 and then, the data line 400 is formed on the first passivation protection layer 300 that is set on and covers the source electrode 240 and the drain electrode 250 of the TFT 200 so that the data line 400 is located on a layer that is different from the source electrode 240 and the drain electrode 250 of the TFT 200.

The data line 400 and the gate electrode 210 can be treated as two metal electrode plates that are opposite to each other and parasitic capacitance Cgd is present between the two. It can be known from a capacitance formula that

Cgd=ε₀εᵣ s/d (1)

where ε₀ indicates the dielectric constant of vacuum, εᵣ is relative dielectric constant of the material, s indicates the area of a surface of the data line 400 opposing the gate electrode 210, and d is the spacing distance between the data line 400 and the gate electrode 210.

For the TFT array substrate manufactured with the array substrate manufacturing method according to the present invention, since the data line 400 and the source electrode 240 and the drain electrode 250 of the TFT 200 are located on different layers, the spacing distance between the data line 400 and the gate electrode 210 is the sum of a thickness of the first passivation protection layer 300 and a thickness of the gate insulation layer 220 and, compared to a conventional TFT array substrate, the spacing distance between the data line 400 and the gate electrode 210 is increased by a thickness of the first passivation protection layer 300. It can be known from formula (1) that the parasitic capacitance Cgd is inversely proportional to the spacing distance between the data line 400 and the gate electrode 210 so that an increase of the spacing distance between the data line 400 and the gate electrode 210 would result in a decrease of the parasitic capacitance Cgd thereby effectively reducing power consumption of the data line 400 and thus power consumption of the TFT array substrate. Further, flexible adjustment of the spacing distance between the data line 400 and the gate electrode 210 can be made by varying the thickness of the first passivation protection layer 300 so as to allow for flexible regulation of the parasitic capacitance Cgd, such as expanding the thickness of the first passivation protection layer 300 to increase the spacing distance between the data line 400 and the gate electrode 210 for decreasing the parasitic capacitance Cgd. It is noted that since the reason that the spacing distance between the data line 400 and the gate electrode 210 is increased is allocating the data line 400 on a layer that is above the first passivation protection layer 300, the thickness of the gate insulation layer 220 is not affected and positions of the source electrode 240 and the drain electrode 250 of the TFT 200 are not changed so that the characteristics of the TFT 200 can be maintained.

In summary, the present invention provides a TFT array substrate, in which a source electrode and a drain electrode of a TFT are formed on a gate insulation layer and a data line is formed on a first passivation protection layer that is set on and covers the source electrode and the drain electrode of the TFT so that the data line and the source electrode and the drain electrode of the TFT are located on different layers and flexible adjustment of a spacing distance between the data line and the gate electrode can be achieved by varying the thickness of the first passivation protection layer, whereby compared to the prior art, the spacing distance between the data line and the gate electrode is expanded; parasitic capacitance between the data line and the gate electrode is reduced; power consumption of the data line is reduced; while the thickness of a gate insulation layer is not affected and positions of the source electrode and the drain electrode of the TFT are not changed so that characteristics of the TFT are maintained stable. The present invention provides a manufacturing method of a TFT array substrate, in which a source electrode and a drain electrode of a TFT are first formed on a gate insulation layer and then, a data line is formed on a first passivation protection layer set on and covering the source electrode and the drain electrode of the TFT so as to maintain the characteristics of the TFT and also reduce parasitic capacitance between the data line and the gate electrode to thereby reducing power consumption of the data line.

Based on the description given above, those having ordinary skills of the art may easily contemplate various changes and modifications of the technical solution and technical ideas of the present invention and all these changes and modifications are considered within the protection scope defiend by the claims of the present invention.

What is claimed is:

1. A thin-film transistor (TFT) array substrate, comprising: a backing plate, a TFT formed on the backing plate, a first passivation protection layer set on and covering the TFT, a data line formed on the first passivation protection layer, a second passivation protection layer set on and covering the first passivation protection layer and the data line, and a pixel electrode formed on the second passivation protection layer;
wherein the TFT comprises: a gate electrode formed on the backing plate, a gate insulation layer set on and covering the gate electrode and the backing plate, an active layer formed on the gate insulation layer and located exactly above the gate electrode, and a source electrode a drain electrode formed on the gate insulation layer and respectively in contact engagement with two ends of the active layer; and
a first via is formed above the drain electrode and extends through the first passivation protection layer and the data line is set in contact engagement with the drain electrode through the first via.

2. The TFT array substrate as claimed in claim 1, wherein the source electrode, the drain electrode, and the data line are formed of the same metallic material.

3. The TFT array substrate as claimed in claim 2, wherein the material of the source electrode, the drain electrode, and the data line comprises one of molybdenum, titanium, aluminum, and copper or a stacked combination of multiple ones thereof.

4. The TFT array substrate as claimed in claim 1, wherein the backing plate comprises a glass plate; the pixel electrode is formed of a material comprising indium tin oxide (ITO); and the gate insulation layer, the first passivation protection layer, and the second passivation protection layer are formed of a material comprising silicon nitride, silicon oxide, or a combination thereof.

5. The TFT array substrate as claimed in claim 1, wherein a second via is formed above the source electrode and extends through the first passivation protection layer and the second passivation protection layer and the pixel electrode is set in contact engagement with the source electrode through the second via.

6. A manufacturing method of a thin-film transistor (TFT) array substrate, comprising the following steps:
(1) providing a backing plate and depositing and patterning a first metal layer on the backing plate to form a gate electrode;
(2) depositing a gate insulation layer on the gate electrode and the backing plate;
(3) forming an active layer on the gate insulation layer to be located exactly above the gate electrode;
(4) conducting a first round of depositing and patterning a second metal layer on the gate insulation layer and the active layer to form a source electrode and a drain electrode that are respectively in contact engagement with two ends of the active layer so as to complete formation of a TFT;
(5) depositing and covering a first passivation protection layer on the source electrode, the drain electrode, and the gate insulation layer and conducting patterning treatment on the first passivation protection layer to form a first via that is located above the drain electrode and extends through the first passivation protection layer;
(6) conducting a second round of depositing and patterning a second metal layer on the first passivation protection layer to form a data line, such that the data line is set in contact engagement with the drain electrode through the first via;
(7) depositing and covering a second passivation protection layer on the first passivation protection layer and the data line and conducting patterning treatment to form a second via that is located above the source electrode and extends through the second passivation protection layer and the first passivation protection layer; and
(8) depositing and patterning a transparent conductive film on the second passivation protection layer to form a pixel electrode, such that the pixel electrode is set in contact engagement with the source electrode through the second via.

7. The manufacturing method of the TFT array substrate as claimed in claim 6, wherein the second metal layer is formed of a material comprising one of molybdenum, titanium, aluminum, and copper or a stacked combination of multiple ones thereof.

8. The manufacturing method of the TFT array substrate as claimed in claim 6, wherein the backing plate comprises a glass plate; the transparent conductive film comprises an indium tin oxide (ITO) film; and the gate insulation layer, the first passivation protection layer, and the second passivation protection layer are formed of a material comprising silicon nitride, silicon oxide, or a combination thereof.

9. A thin-film transistor (TFT) array substrate, comprising: a backing plate, a TFT formed on the backing plate, a first passivation protection layer set on and covering the TFT, a data line formed on the first passivation protection layer, a second passivation protection layer set on and covering the first passivation protection layer and the data line, and a pixel electrode formed on the second passivation protection layer;
wherein the TFT comprises: a gate electrode formed on the backing plate, a gate insulation layer set on and covering the gate electrode and the backing plate, an active layer formed on the gate insulation layer and located exactly above the gate electrode, and a source electrode a drain electrode formed on the gate insulation layer and respectively in contact engagement with two ends of the active layer; and
a first via is formed above the drain electrode and extends through the first passivation protection layer and the data line is set in contact engagement with the drain electrode through the first via;
wherein the source electrode, the drain electrode, and the data line are formed of the same metallic material; and
wherein the backing plate comprises a glass plate; the pixel electrode is formed of a material comprising indium tin oxide (ITO); and the gate insulation layer, the first passivation protection layer, and the second passivation protection layer are formed of a material comprising silicon nitride, silicon oxide, or a combination thereof.

10. The TFT array substrate as claimed in claim 9, wherein the material of the source electrode, the drain electrode, and the data line comprises one of molybdenum, titanium, aluminum, and copper or a stacked combination of multiple ones thereof.

11. The TFT array substrate as claimed in claim 9, wherein a second via is formed above the source electrode and extends through the first passivation protection layer and the second passivation protection layer and the pixel electrode is set in contact engagement with the source electrode through the second via.
